(19) United States
(12) Patent Application Publication
(10) Pub. No.: US 2008/0042694 A1
(43) Pub. Date: Feb. 21, 2008

(54) INTEGRATED CMOS CIRCUIT WITH DIFFERENTIAL OPEN DRAIN OUTPUT DRIVER

(75) Inventor: Gerd Rombach, Freising (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 11/841,461

(22) Filed: Aug. 20, 2007

(30) Foreign Application Priority Data
Aug. 18, 2006 (DE) 10 2006 038 870.4

(51) Int. Cl. H03K 5/22

(52) U.S. Cl. 327/66; 327/65

(57) ABSTRACT

An integrated CMOS circuit with a differential open drain output driver comprises a plurality of differential output stages each having differential inputs and differential outputs, the differential outputs of the differential output stages being interconnected to provide a pair of differential open drain driver outputs, and the differential inputs of the differential output stages being driven by a pair of inverter chains each of which has an input receiving one of a pair of differential input signals and cascaded inverter stages each with an output connected to an input of one of the differential output stages.

The invention relates to an integrated CMOS circuit with a differential open drain output driver.

### BACKGROUND

Signal interfaces operating at frequencies above 1 GHz are differential by nature, be it clock or data signals. With a low voltage swing and due to the common mode noise rejection these interfaces are able to transmit high speed signals in a noisy environment without failures. Conventionally, such interface circuits are implemented in bipolar technology, emitter-coupled logic (ECL) or positive emitter-coupled logic (PECL).

For high scale integrated circuits, there is a need to have differential output stages in CMOS technology, as opposed to a BiCMOS technology that requires additional process steps. While differential output stages can be implemented in “pure” CMOS technology, they have drawbacks. A first drawback is the limited ability to define the output transition time. A second drawback is the input signal offset.

Specifically, with reference to FIG. 1, a prior art output driver 10 comprises a pair of differential output transistors MN01 and MN02, which form an output branch and an inverted output branch configured to produce outputs outb and out, respectively, with outb being the inverse of out. Signals in1 and inb1 are applied to the gates of the transistors MN01 and MN02, respectively. The input signals to the driver 10, in1 and inb1, are derived out of digital core logic from a pair of inverters acting as buffers BU1 and BU2, as illustrated in FIG. 2.

A source current is supplied to the source of each of the transistors MN01 and MN02 from a current mirror, which mirrors a reference current iref. The signals in1 and inb1 will be rail to rail (have a full voltage swing) and buffered by buffers BU1 and BU2. In the driver 10, the output rise and fall time cannot be set by changing the source current because the current has to have a fixed value that defines the output voltage swing across a line termination resistor. The current will be switched from one branch to its inverting branch and the sum of both has to be constant all the time.

The output transition time of the driver 10 could be set by an external load capacitor. With this approach, there would be a resistive mismatch between the transistors MN01 and MN02. Furthermore, a load capacitor leads to increased consumption of current, cost in terms of an external capacitive load, and performance degradation in terms of the maximal output frequency. A second approach to controlling the output transition time could be to slow down the voltage slope at the gates of the differential pair transistors MN01 and MN02 by control of the input signals in1 and inb1. However, this would lead to an increased signal propagation time through the driver 10 and an increased sensitivity to noise on the power supply lines.

### SUMMARY

The invention overcomes these problems and provides an integrated circuit with a differential open drain output driver in “pure” CMOS technology. Specifically, the integrated circuit of the invention includes at least one differential open drain output driver. The output driver comprises a plurality of differential output stages, each having differential inputs and differential outputs. The differential outputs of the differential output stages are interconnected to provide a pair of differential open drain driver outputs. The differential inputs of the differential output stages are driven by a pair of inverter chains, each of which has an input receiving one of a pair of differential input signals and cascaded inverter stages each with an output connected to an input of one of the differential output stages. Each inverter stage in the inverter chains introduces a propagation delay. Therefore, fractions of the entire output current are switched successively and in discrete time steps. Accordingly, the rise and fall times can be defined as required by adjusting the timed current contributions of each output stage. A preferred way is weighting the current in the output stages, thereby staggering the output stages.

In a preferred embodiment, output nodes of successive inverter stages in each inverter chain are all connected to differential inputs of same polarity, opposite to the polarity of differential input signals applied to an input of the first inverter in each inverter chain. Such cross-coupling provides automatic compensation for any offset of the input signal.

Preferably, each differential output stage includes a source circuit with a current mirror that mirrors a reference current. The differential output stages are preferably staggered in terms of current supplied by the associated current mirrors. The current mirror of the output stage driven by a last one of the inverter stages of each inverter chain should preferably supply a substantially higher current than the current mirror of the output stage driven by a first one of the inverter stages in each inverter chain.

### BRIEF DESCRIPTION OF THE DRAWINGS

Further advantages and characteristics of the invention will be apparent from the below description of an example preferred implementation, and from the accompanying drawings, wherein:

FIG. 1 (Prior Art) is a circuit diagram of a prior art output driver;

FIG. 2 (Prior Art) is a diagram showing the input buffers for the prior art driver of FIG. 1;

FIG. 3 is an output driver according to the principles of the invention;

FIG. 4 is a diagram of an inverter delay chain for providing the input to the driver according to the invention;

FIG. 5 is a representation of waveforms of the inverter delay chain and the consequential output curves of the output driver according to the invention;

FIG. 6 is a representation of waveforms of the inverting delay chain with an input offset and the resulting output curves of an output driver according to the invention; and

FIG. 7 is a representation of waveforms of a buffering delay chain with an input offset and the output curves of the output driver.

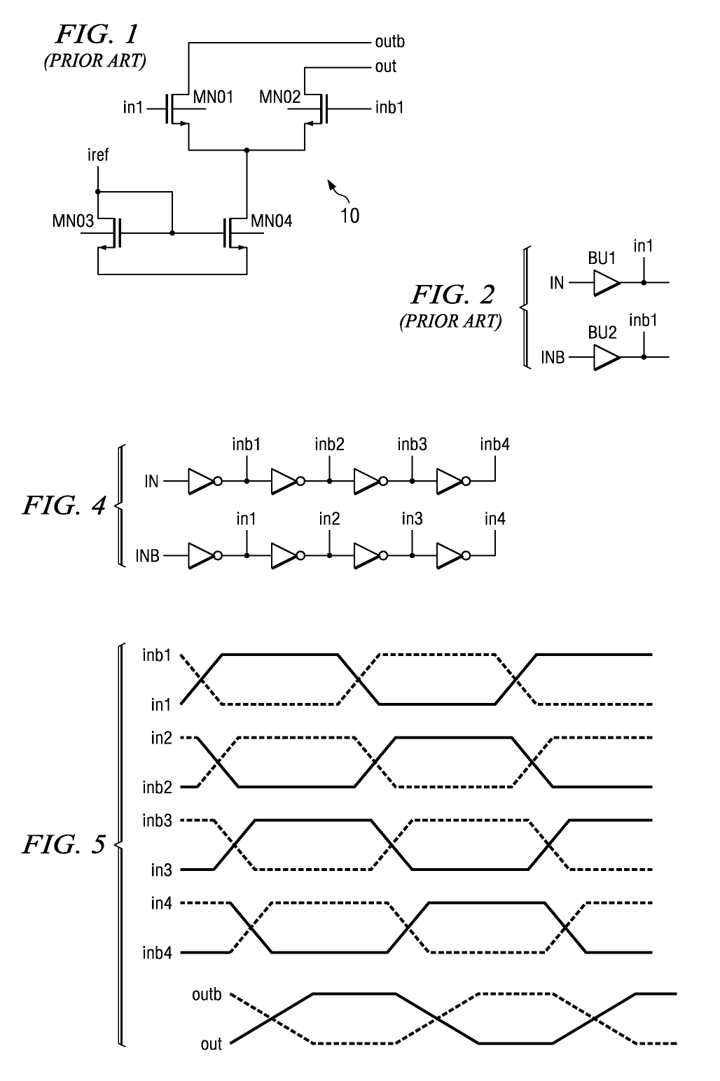

### DETAILED DESCRIPTION OF EXAMPLE EMBODIMENTS

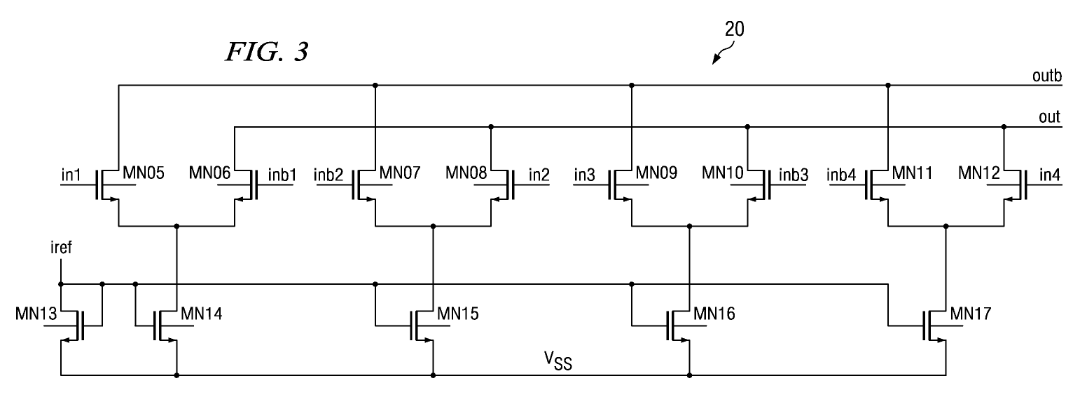

Referring now to FIG. 3, an output driver 20 according to the invention comprises four output stages. Each output stage comprises a pair of MOS transistors MN05, MN06; MN07, MN08; MN09, MN10; and MN11, MN12, respectively. Each pair of transistors has a common source input. The gate of each of the transistors MN05, MN07, MN09 and MN11 is connected to an input in1, inb2, in3 and inb4, respectively, and the gate of each of the transistors MN06, MN08, MN10 and MN12 is connected to an input inb1, in2, inb3 and in4, respectively. Each of the inputs inb1, inb2, inb3 and inb4 is provided by an inverter delay chain IN, and each of the inputs in1, in2, in3 and in4 is provided by an inverter delay chain INB. The pair of cascaded inverter chains IN and INB is shown in FIG. 4. Each output stage has two outputs, outb and out. The drains of each of the transistors MN05, MN07, MN09 and MN11 are interconnected to provide the outb output and the drains of each of the CMOS transistors MN06, MN08, MN10 and MN12 are interconnected to provide the out output.

A current mirror is connected to each output stage at the source of each of the transistors MN05-MN12. Each of the current mirrors comprises a MOS transistor MN14, MN15, MN16 and MN17 a connected to a common MOS transistor MN13. The gate and the drain of transistor MN13 are interconnected, and connected to the gates of each transistor MN14, MN15, MN16 and MN17. The sources of transistors MN13, MN14, MN15, MN16 and MN17 are commonly connected to a supply terminal V_{SS}. The drains of transistors MN14, MN15, MN16 and MN17 are respectively connected to the interconnected sources of the pairs of transistors MN05, MN06; MN07, MN08; MN09, MN10; and MN11, MN12.

A reference current iref provides the input to the diode-connected transistor MN13. The reference current iref is mirrored by the four current mirrors MN14, MN15, MN16 and MN17. The current mirror transistors MN14, MN15, MN16 and MN17 are dimensioned and configured so that the current supplied to the source of each of the transistors in transistor pair MN05, MN06 in the first output stage is the smallest, and the current supplied to the source of each of the transistors in the transistor pair MN11, MN12 at the last output stage is the largest.

Signals are then applied to the gates of each of the transistors MN05 to MN12 from the two inverter chains IN and INB. The inverter chain INB provides the inputs in1, in2, in3 and in4, which drive a corresponding one of the transistors MN05, MN08, MN09 and MN12 of the transistor pairs in each of the output stages, respectively; and the inverter chain IN provides the inputs inb1, inb2, inb3 and inb4, which drive the corresponding other one of the transistors MN06, MN07, MN08 and MN09 of the transistor pairs in each of the output stages, respectively. The signals in1, inb2, in3 and inb4 force the output from the corresponding transistors to be of one polarity, and the signals inb1, in2, inb3 and in4 force the output from the corresponding transistors to be of opposite polarity, resulting in a pair of differential open drain driver outputs at outb and out. Thus, each output stage is a differential output stage and the differential output stages are staggered in terms of current supplied by the associated current mirrors.

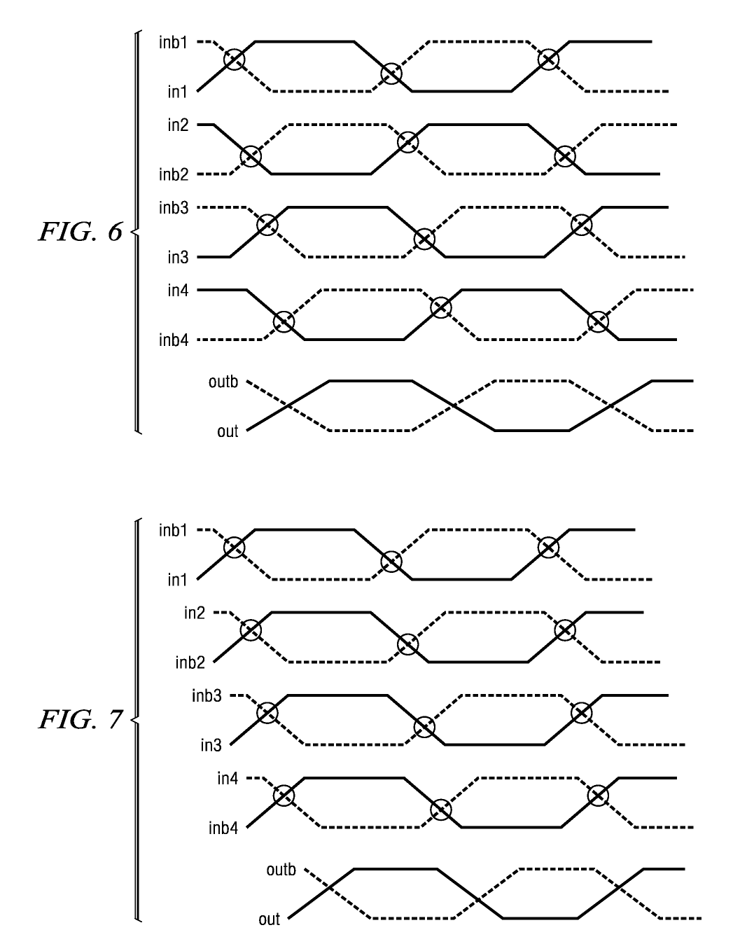

The inputs in, inb1, in2, inb2, in3, inb3, in4 and inb4 to the driver 20, and the corresponding outputs out and outb, are shown in FIG. 5. It can be seen that the voltage cross-point for each inverter stage is at the same voltage level and without an input offset. However, in the event of an input signal offset, as shown in FIG. 6, any input signal offset is compensated for by cross-coupling the signals from the inverter delay chains IN and INB at each of the staggered output stages. Only four inverting stages and four output stages are shown in this embodiment, however, a greater number of stages can be provided in the output driver circuit. If there should be an input offset, as the number of inverting stages is increased, the voltage crossing point can be averaged out further, and therefore the output becomes increasingly more stable.

If non-inverting input buffers are used in the delay chain to provide the inputs to the driver, instead of inverter chains, then the signals at the input buffers will never be exactly complementary. Their offset will cause a voltage cross-point variation at the gates of the differential pair transistors. This is shown in FIG. 7. The differential stage can compensate for this variation only to a certain extent and the voltage cross-point variation will be translated into duty cycle disruption at the output.

An advantage of the driver 20 is that that fractions of the entire output current can be switched successively and in discrete time steps. Therefore, the rise and fall times of the output can be adjusted as required by weighting the current supplied to each output stage. Also, the use of an inverter delay chain to provide the differential inputs to the driver prevents the occurrence of a duty cycle disruption at the output. Furthermore, because the driver displays a short overall propagation delay time and fast internal transitions, the circuit shows a good phase noise performance. The driver circuit can also be implemented purely in CMOS technology.

Although the invention has been described above with reference to a specific example implementation, those skilled in the art to which the invention relates will appreciate that there are other ways to implement the claimed invention.

What is claimed is:

1. An integrated CMOS circuit with a differential open drain output driver, comprising a plurality of differential output stages and a pair of inverter chains; each differential output stage having differential inputs and differential output, with corresponding ones of the differential outputs of the plurality of differential output stages being interconnected to provide a pair of differential open drain driver outputs, and with corresponding ones of the differential inputs of the plurality of differential output stages being driven by a respective one of the inverter chains; each inverter chain having an input receiving one of a pair of differential input signals and comprising a plurality of cascaded inverter stages, each with an output connected to a respective input of one of the differential output stages.

2. The circuit of claim 1, wherein output nodes of successive inverter stages in each inverter chain are connected to differential inputs of a same polarity, opposite to the polarity of differential input signals applied to an input of the first inverter in each inverter chain.

3. The circuit of claim 2, wherein each differential output stage includes a source circuit with a current mirror that mirrors a reference current.

4. The circuit of claim 3, wherein the differential output stages are staggered in terms of current supplied by the associated current mirrors.

5. The circuit of claim 4, wherein the current mirror of the output stage driven by a last one of the inverter stages of each inverter chain supplies a substantially higher current than the current mirror of the output stage driven by a first one of the inverter stages in each inverter chain.

6. The circuit of claim 1, wherein each differential output stage includes a source circuit with a current mirror that mirrors a reference current.

7. The circuit of claim 6, wherein the differential output stages are staggered in terms of current supplied by the associated current mirrors.

8. The circuit of claim 7, wherein the current mirror of the output stage driven by a last one of the inverter stages of each inverter chain supplies a substantially higher current than the current mirror of the output stage driven by a first one of the inverter stages in each inverter chain.

9. The circuit of claim 6, wherein the current mirror of the output stage driven by a last one of the inverter stages of each inverter chain supplies a substantially higher current than the current mirror of the output stage driven by a first one of the inverter stages in each inverter chain.
